(19) United States
(12) Patent Application Publication
(10) Pub. No.: US 2026/0344540 A1
(43) Pub. Date: Oct. 29, 2026

(54) SEMICONDUCTOR DEVICE AND VEHICLE

(71) Applicant: ROHM CO., LTD., Kyoto-shi (JP)

(72) Inventors: Masashi HAYASHIGUCHI, Kyoto-shi (JP); Yoshihisa TSUKAMOTO, Kyoto-shi (JP); Hidetoshi ABE, Kyoto-shi (JP); Hideki SAWADA, Kyoto-shi (JP)

(21) Appl. No.: 19/655,967

(22) Filed: Apr. 23, 2026

Related U.S. Application Data
(63) Continuation of application No. PCT/JP2024/037322, filed on Oct. 21, 2024.

(30) Foreign Application Priority Data
Oct. 30, 2023 (JP) 2023-185208

(51) Int. Cl. H10W 90/20; H02M 7/00; H05K 7/20; H10W 40/20; H10W 40/22; H10W 40/43; H10W 40/47; H10W 70/20; H10W 90/00; H10W 90/10; H10W 90/22

(52) U.S. Cl. CPC H10W 90/288; H02M 7/003; H05K 7/209; H10W 40/226; H10W 40/235; H10W 40/43; H10W 40/47; H10W 70/24; H10W 90/10; H10W 90/22; H10W 90/766

(57) ABSTRACT

A semiconductor device includes a first terminal, and a first semiconductor element electrically bonded to the first terminal. The first terminal includes a first obverse surface facing one side in a first direction. The first terminal is provided with a first heat dissipating portion that protrudes from the first obverse surface. The first terminal is provided with a first opening formed in the first obverse surface. The first opening is connected to the first heat dissipating portion.

### TECHNICAL FIELD

The present disclosure relates to a semiconductor device and a vehicle equipped with the semiconductor device.

### BACKGROUND ART

WO 2017/094370 discloses an example of a semiconductor module that is equipped with a semiconductor device and a cooling unit. The cooling unit includes a housing having a hollow region and a heat dissipator. The housing is formed with an opening that leads into the hollow region. The heat dissipator is attached to the housing to cover the opening. The heat dissipator is partially housed in the hollow region. The semiconductor device is bonded to a portion of the heat dissipator that extends outward from the hollow region. When a coolant (such as cooling water) flows into the hollow region, the coolant comes into contact with the heat dissipator. In this way, the semiconductor device is cooled efficiently through the heat dissipator.

However, in the configuration of the semiconductor module disclosed in WO 2017/094370, a sufficient cooling effect for the semiconductor device is not achieved relative to the size of the cooling unit.

### BRIEF DESCRIPTION OF THE DRAWINGS

FIG. 1 is a plan view showing a semiconductor device according to a first embodiment of the present disclosure.

FIG. 2 is a plan view corresponding to FIG. 1, in which a housing is shown as transparent.

FIG. 3 is a plan view corresponding to FIG. 2, in which a fourth terminal is omitted.

FIG. 4 is a plan view corresponding to FIG. 3, in which a second terminal, a conductive member, a third signal terminal, a fourth signal terminal, a plurality of second semiconductor elements, a plurality of third leads, and a plurality of fourth leads are omitted.

FIG. 5 is a plan view corresponding to FIG. 4, in which a first terminal is omitted.

FIG. 6 is a bottom view showing the semiconductor device in FIG. 1.

FIG. 7 is a cross-sectional view along line VII-VII in FIG. 3.

FIG. 8 is a cross-sectional view along line VIII-VIII in FIG. 3.

FIG. 9 is a cross-sectional view along line IX-IX in FIG. 3.

FIG. 10 is a partially enlarged view of FIG. 8, showing one of a plurality of first semiconductor elements and the vicinity of the first semiconductor element.

FIG. 11 is a partially enlarged view of FIG. 8, showing one of the second semiconductor elements and the vicinity of the second semiconductor element.

FIG. 12 is a partially enlarged view of FIG. 7.

FIG. 13 is a cross-sectional view showing the state where a coolant flows downward in the semiconductor device of FIG. 1.

FIG. 14 is a partially enlarged cross-sectional view showing a semiconductor device according to a first variation of the first embodiment in the present disclosure.

FIG. 15 is a partially enlarged cross-sectional view showing a semiconductor device according to a second variation of the first embodiment in the present disclosure.

FIG. 16 is a schematic view showing a vehicle equipped with the semiconductor device in FIG. 1.

FIG. 17 is a plan view showing a semiconductor device according to a second embodiment of the present disclosure, and corresponds to FIG. 4.

FIG. 18 is a cross-sectional view showing the semiconductor device in FIG. 17, and corresponds to FIG. 7.

FIG. 19 is a cross-sectional view showing a semiconductor device according to a third embodiment of the present disclosure, and corresponds to FIG. 7.

FIG. 20 is a cross-sectional view showing the semiconductor device in FIG. 19, and corresponds to FIG. 8.

FIG. 21 is a plan view showing a semiconductor device according to a fourth embodiment of the present disclosure.

FIG. 22 is a plan view showing the semiconductor device in FIG. 21, and corresponds to FIG. 2.

FIG. 23 is a plan view showing the semiconductor device in FIG. 21, and corresponds to FIG. 4.

FIG. 24 is a plan view showing the semiconductor device in FIG. 21, and corresponds to FIG. 5.

FIG. 25 is a cross-sectional view along line XXV-XXV in FIG. 22.

FIG. 26 is a cross-sectional view along line XXVI-XXVI in FIG. 22.

### DETAILED DESCRIPTION OF EMBODIMENTS

Details of the present disclosure will be described with reference to the accompanying drawings.

### First Embodiment

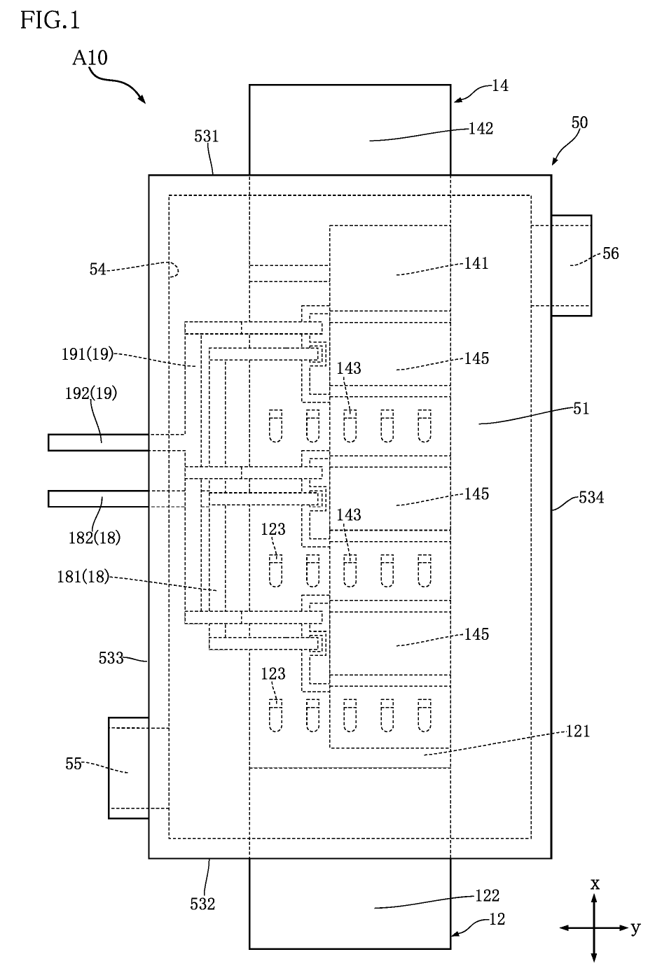

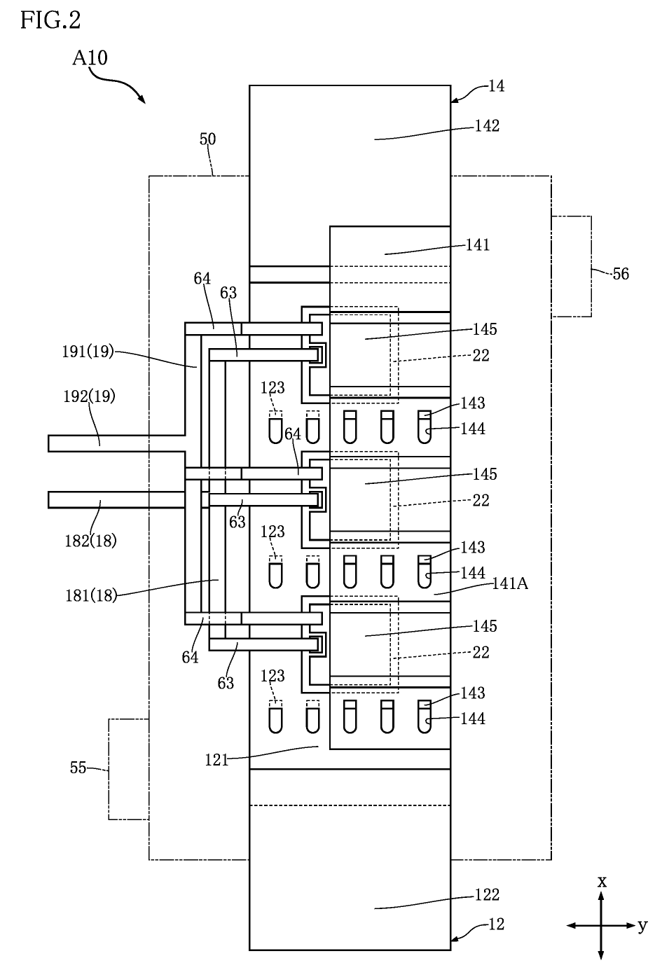

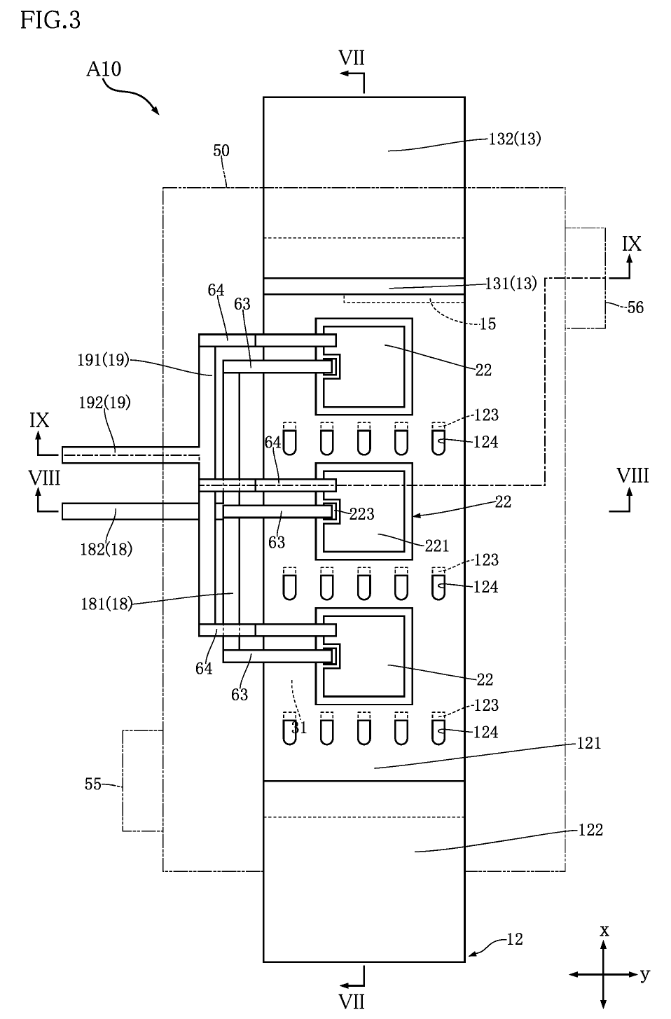

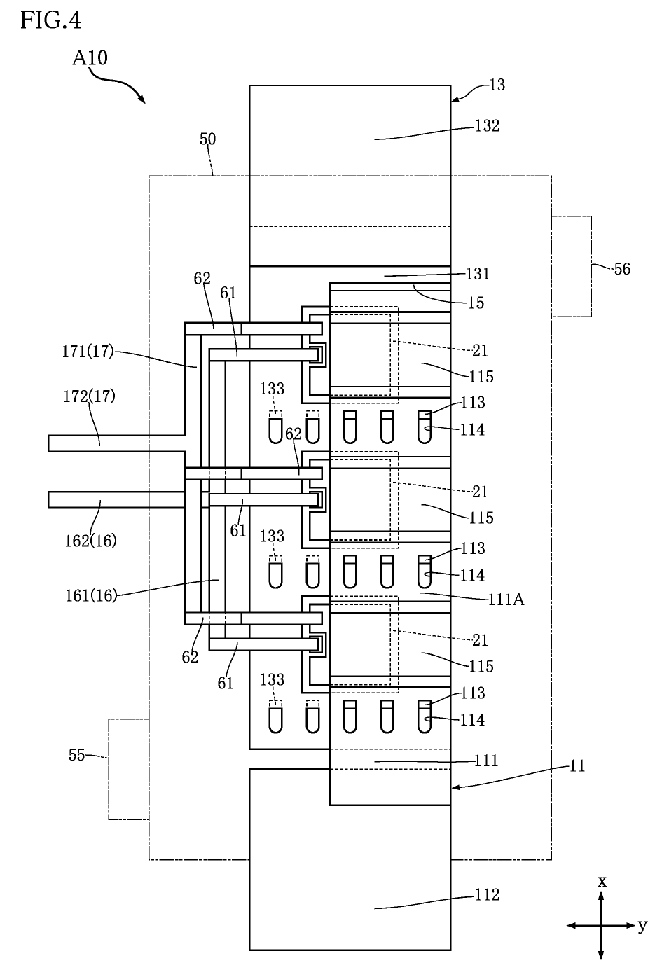

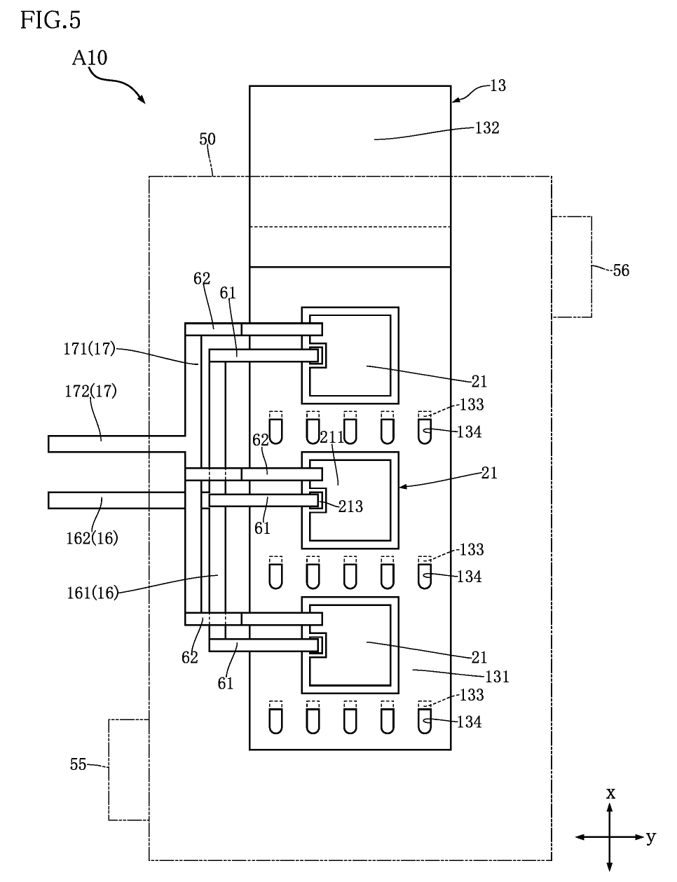

The following describes a semiconductor device A10 according to a first embodiment of the present disclosure, with reference to FIGS. 1-13. The semiconductor device A10 is typically used in a power conversion circuit, such as an inverter. The semiconductor device A10 includes a first terminal 11, a second terminal 12, a third terminal 13, a fourth terminal 14, a conductive member 15, a plurality of first semiconductor elements 21, a plurality of second semiconductor elements 22, and a housing 50. The semiconductor device A10 further includes a first signal terminal 16, a second signal terminal 17, a third signal terminal 18, a fourth signal terminal 19, a plurality of first leads 61, a plurality of second leads 62, a plurality of third leads 63, and a plurality of fourth leads 64. For convenience of understanding, FIGS. 2-5 show the housing 50 as transparent. FIGS. 2-5 show the housing 50 with imaginary lines (two-dot chain lines). For convenience of understanding, FIG. 3 omits the fourth terminal 14 shown in FIG. 2. For convenience of understanding, FIG. 4 omits the second terminal 12, the conductive member 15, the third signal terminal 18, the fourth signal terminal 19, the second semiconductor elements 22, the third leads 63, and the fourth leads 64 that are shown in FIG. 3. For convenience of understanding, FIG. 5 omits the first terminal 11 shown in FIG. 4.

For convenience in the description of the semiconductor device A10, the direction normal to a first obverse surface 111A (described below) of the first terminal 11 will be referred to as "first direction z". A direction perpendicular to the first direction z will be referred to as "second direction x". The direction perpendicular to both of the first direction z and the second direction x will be referred to as "third direction y".

The semiconductor device A10 is configured with a half-bridge circuit including the first semiconductor elements 21 and the second semiconductor elements 22. The semiconductor device A10 uses the first semiconductor elements 21 and the second semiconductor elements 22 to convert the DC power supplied to the third terminal 13 and the fourth terminal 14 into AC power. The third terminal 13 is a P terminal (positive electrode). The fourth terminal 14 is an N terminal (negative electrode). The AC power generated by the conversion is inputted from the first terminal 11 and the second terminal 12 to a load, such as a motor.

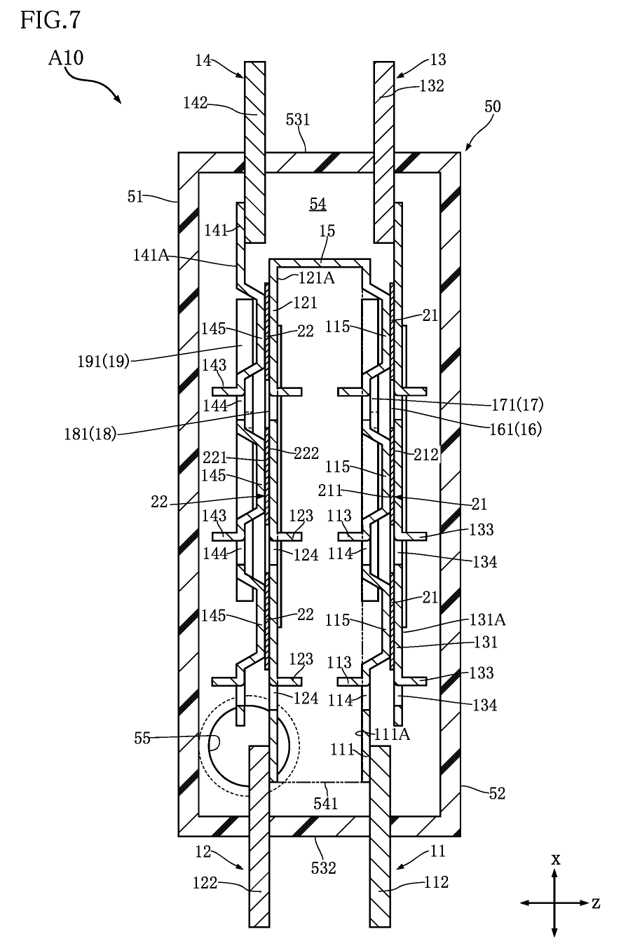

As shown in FIGS. 7 - 9, the housing 50 supports the first terminal 11, the second terminal 12, the third terminal 13, the fourth terminal 14, the first signal terminal 16, the second signal terminal 17, the third signal terminal 18, and the fourth signal terminal 19. The housing 50 is made of an insulating material containing resin. Alternatively, the housing 50 may be made of a conductive material containing a metal such as aluminum (Al).

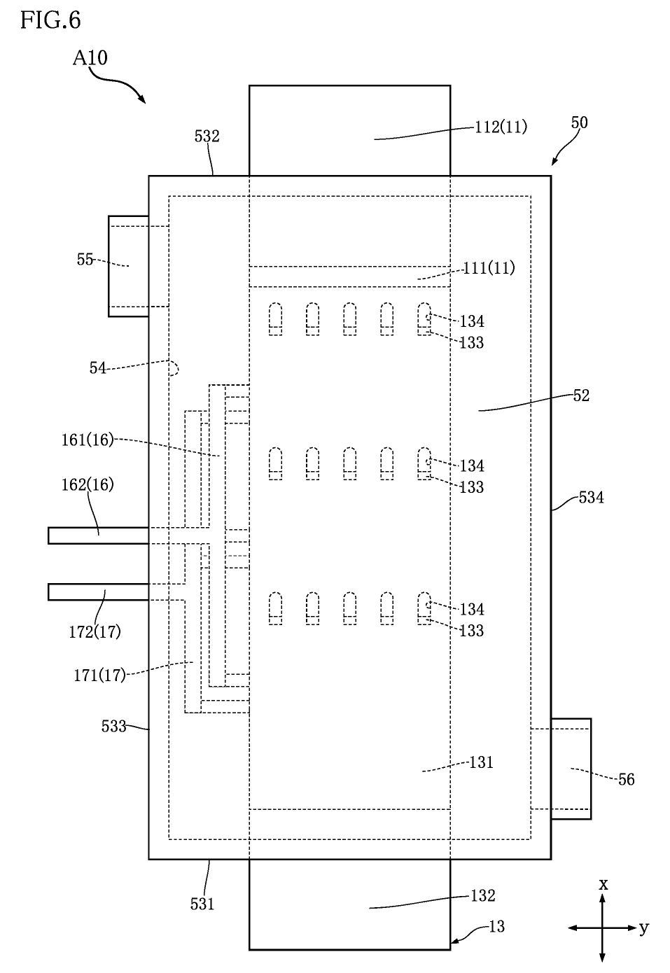

As shown in FIGS. 1 and 6, the housing 50 has a top surface 51, a bottom surface 52, a first side surface 531, a second side surface 532, a third side surface 533, and a fourth side surface 534. The top surface 51 faces one side in the first direction z. The bottom surface 52 faces away from the top surface 51 in the first direction z. The first side surface 531 and the second side surface 532 face away from each other in the second direction x. The third side surface 533 and the fourth side surface 534 face away from each other in the third direction y.

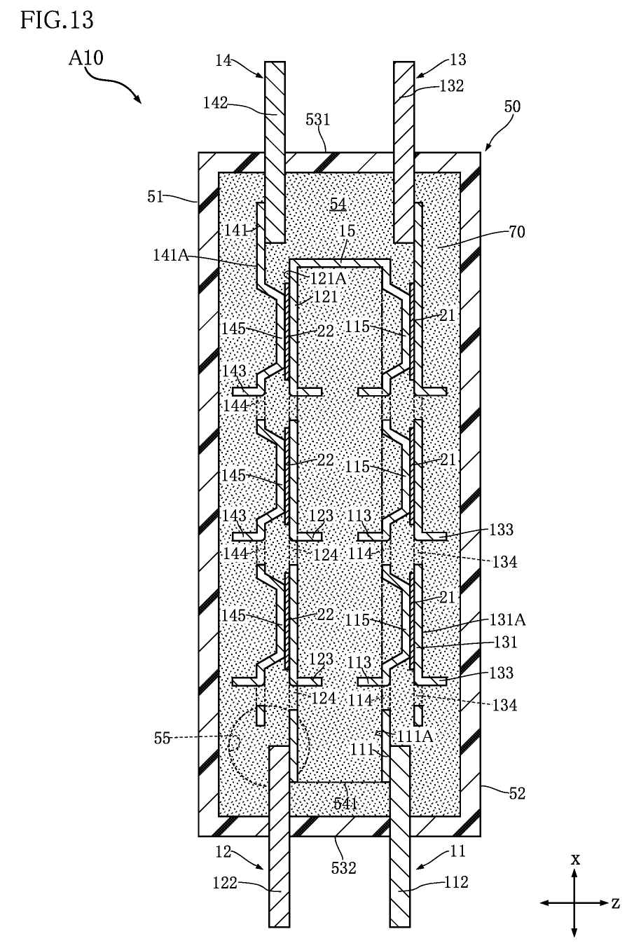

As shown in FIGS. 7-9, the housing 50 has a cavity 54. The cavity 54 is in communication with ambient air. Alternatively, as shown in FIG. 13, the cavity 54 may be configured to be constantly filled with a coolant 70. The cavity 54 includes a flow path 541. The flow path 541 is provided between the first terminal 11 and the second terminal 12 in the first direction z. Note that the coolant 70 shown FIG. 13 needs to be an insulator. In the present disclosure, the coolant 70 may have any composition as long as the coolant 70 is an insulator.

As shown in FIGS. 1, 3, 4, and 6, the housing 50 has an inlet 55 and an outlet 56. The inlet 55 is provided in the third side surface 533 and is in communication with the cavity 54. The outlet 56 is provided in the fourth side surface 534 and is in communication with the cavity 54. The coolant 70 shown in FIG. 13 enters the housing 50 through the inlet 55 and flows into the cavity 54. Subsequently, the coolant 70 in the cavity 54 exits through the outlet 56. As shown in FIGS. 3 and 4, the inlet 55 and the outlet 56 are positioned opposite each other with respect to a plurality of first heat dissipating portions 113 (details of which are described below) of the first terminal 11 in the second direction x.

As shown in FIGS. 7 - 9, the first terminal 11 is positioned on one side in the first direction z from the first semiconductor elements 21. The first terminal 11 is a metal plate containing copper (Cu), for example. As shown in FIGS. 4 and 7, the first terminal 11 has a first base 111, a first extension 112, and a plurality of first connecting portions 115. The first base 111 is accommodated in the cavity 54 of the housing 50 and is in contact with the flow path 541. The first extension 112 is electrically bonded to the first base 111 on one side in the second direction x. The first extension 112 is supported by the housing 50. The first extension 112 has a portion protruding outward from the second side surface 532 of the housing 50. The first connecting portions 115 are connected to the first base 111. Each of the first connecting portions 115 protrudes from the first base 111 toward the first semiconductor elements 21 in the first direction z. The first connecting portions 115 are aligned along the second direction x.

As shown in FIGS. 4 and 7, the first base 111 of the first terminal 11 is provided with a plurality of first heat dissipating portions 113 and a plurality of first openings 114. The first base 111 has a first obverse surface 111A facing the same side as the top surface 51 of the housing 50 in the first direction z. The first heat dissipating portions 113 protrude from the first obverse surface 111A. The first heat dissipating portions 113 are spaced apart from the first connecting portions 115. The first heat dissipating portions 113 are accommodated in the flow path 541 of the cavity 54 of the housing 50. The first openings 114 are formed in the first obverse surface 111A. The first openings 114 pass through the first base 111 in the first direction z. The first openings 114 are connected to the respective first heat dissipating portions 113.

As shown in FIG. 12, the first heat dissipating portions 113 extend in the first direction z. The volume of each first heat dissipating portion 113 is equal to the volume of each first opening 114. The thickness (the dimension in the second direction x) of each first heat dissipating portion 113 is equal to the dimension of the first base 111 in the first direction z.

As shown in FIGS. 7-9, the second terminal 12 is positioned opposite the first semiconductor elements 21 with respect to the first obverse surface 111A of the first terminal 11 in the first direction z. The second terminal 12 is a metal plate containing copper, for example. The second terminal 12 has a second base 121 and a second extension 122. The second base 121 is accommodated in the cavity 54 of the housing 50 and is in contact with the flow path 541 and a third flow path 543. The second extension 122 is electrically bonded to the second base 121 on one side in the second direction x. The second extension 122 is supported by the housing 50. The second extension 122 has a portion protruding outward from the second side surface 532 of the housing 50.

As shown in FIGS. 3 and 7, the second base 121 of the second terminal 12 is provided with a plurality of second heat dissipating portions 123 and a plurality of second openings 124. The second base 121 has a second obverse surface 121A facing the first obverse surface 111A of the first terminal 11 in the first direction z. The second heat dissipating portions 123 protrude from the second obverse surface 121A. As viewed in the first direction z, the second heat dissipating portions 123 overlap with the respective first heat dissipating portions 113 of the first terminal 11. The second heat dissipating portions 123 are accommodated in the flow path 541 of the cavity 54 of the housing 50. The second openings 124 are formed in the second obverse surface 121A. The second openings 124 pass through the second base 121 in the first direction z. The second openings 124 are connected to the respective second heat dissipating portions 123.

As shown in FIGS. 7-9, the third terminal 13 is positioned opposite the first terminal 11 with respect to the first semiconductor elements 21 in the first direction z. The third terminal 13 is a metal plate containing copper, for example. The third terminal 13 has a third base 131 and a third extension 132. The third base 131 is accommodated in the cavity 54 of the housing 50. The third extension 132 is electrically bonded to the third base 131 on one side in the second direction x. The third extension 132 is supported by the housing 50. The third extension 132 has a portion protruding outward from the first side surface 531 of the housing 50.

As shown in FIGS. 5 and 7, the third base 131 of the third terminal 13 is provided with a plurality of third heat dissipating portions 133 and a plurality of third openings 134. The third base 131 has a third obverse surface 131A facing away from the side that faces the first semiconductor elements 21 in the first direction z. The third heat dissipating portions 133 protrude from the third obverse surface 131A. The third openings 134 are formed in the third obverse surface 131A. The third openings 134 pass through the third base 131 in the first direction z. The third openings 134 are connected to the respective third heat dissipating portions 133.

As shown in FIGS. 7-9, the fourth terminal 14 is positioned opposite the second terminal 12 with respect to the second semiconductor elements 22 in the first direction z. The fourth terminal 14 is a metal plate containing copper, for example. The fourth terminal 14 has a fourth base 141, a fourth extension 142, and a plurality of second connecting portions 145. The fourth base 141 is accommodated in the cavity 54 of the housing 50. The fourth extension 142 is electrically bonded to the fourth base 141 on one side in the second direction x. The fourth extension 142 is supported by the housing 50. The fourth extension 142 has a portion protruding outward from the first side surface 531 of the housing 50. The second connecting portions 145 are connected to the fourth base 141. Each of the second connecting portions 145 protrudes from the fourth base 141 toward the second semiconductor elements 22 in the first direction z. The second connecting portions 145 are aligned along the second direction x.

As shown in FIGS. 2 and 7, the fourth base 141 of the fourth terminal 14 is provided with a plurality of fourth heat dissipating portions 143 and a plurality of fourth openings 144. The fourth base 141 has a fourth obverse surface 141A facing the same side as the top surface 51 of the housing 50 in the first direction z. The fourth heat dissipating portions 143 protrude from the fourth obverse surface 141A. The fourth heat dissipating portions 143 are spaced apart from the second connecting portions 145. The fourth openings 144 are formed in the fourth obverse surface 141A. The fourth openings 144 pass through the fourth base 141 in the first direction z. The fourth openings 144 are connected to the respective fourth heat dissipating portions 143.

As shown in FIGS. 3, 4, and 7, the conductive member 15 connects the first base 111 of the first terminal 11 and the second base 121 of the second terminal 12 on one side in the second direction x. As a result, the first terminal 11 and the second terminal 12 are electrically connected to each other. The conductive member 15 is a metal plate containing copper, for example. The conductive member 15 is accommodated in the cavity 54 of the housing 50. In the semiconductor device A10, the first terminal 11, the second terminal 12, and the conductive member 15 are formed from a single member.

As shown in FIGS. 7-9, the first semiconductor elements 21 are positioned opposite the second terminal 12 with respect to the first terminal 11 in the first direction z. Thus, the first semiconductor elements 21 are positioned opposite the first heat dissipating portions 113 with respect to the first obverse surface 111A of the first terminal 11. In addition, the first semiconductor elements 21 are positioned between the first connecting portions 115 of the first terminal 11 and the third base 131 of the third terminal 13. The first semiconductor elements 21 are accommodated in the cavity 54 of the housing 50. All of the first semiconductor elements 21 are identical. The first semiconductor elements 21 are MOSFETs (metal-oxide-semiconductor field-effect transistors), for example. Alternatively, the first semiconductor elements 21 may be field-effect transistors, including MISFETs (metal-insulator-semiconductor field-effect transistors), or bipolar transistors, including IGBTs (insulated gate bipolar transistors). In the description of the semiconductor device A10 below, the first semiconductor elements 21 are assumed to be n-channel, vertical MOSFETs. Each of the first semiconductor elements 21 includes a compound semiconductor substrate. The compound semiconductor substrate contains silicon carbide (SiC). The first semiconductor elements 21 are aligned along the second direction x.

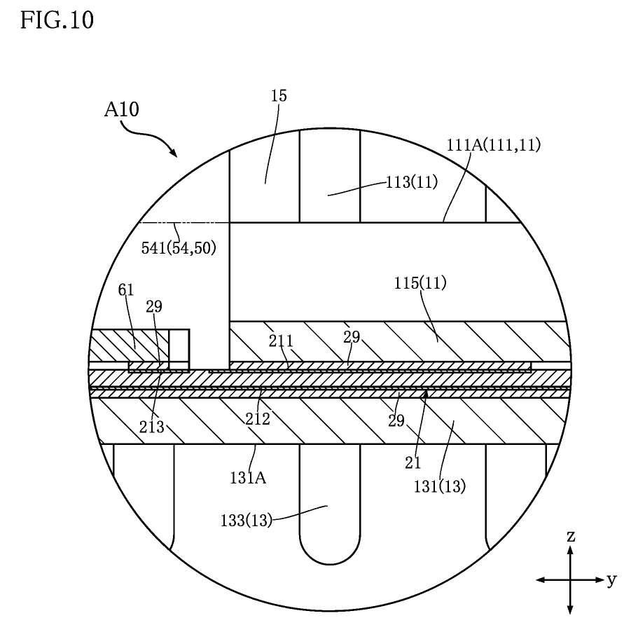

As shown in FIG. 10, each of the first semiconductor elements 21 has a first electrode 211, a second electrode 212, and a first gate electrode 213.

As shown in FIG. 10, the first electrode 211 is positioned opposite the side that faces the third base 131 of the third terminal 13 in the first direction z. The first electrode 211 of each first semiconductor element 21 is electrically bonded to one of the first connecting portions 115 of the first terminal 11 via a bonding layer 29. As a result, the first electrode 211 is electrically connected to the first terminal 11 and the second terminal 12. The bonding layer 29 is solder. Alternatively, the bonding layer 29 may be a sintered metal containing silver (Ag), for example. The first electrode 211 carries the current corresponding to the power after conversion by the first semiconductor element 21. In other words, the first electrode 211 corresponds to the source of the first semiconductor element 21.

As shown in FIG. 10, the second electrode 212 faces the third base 131 of the third terminal 13. The second electrode 212 is electrically bonded to the third base 131 via a bonding layer 29. The second electrode 212 carries the current corresponding to the power before conversion by the first semiconductor element 21. In other words, the second electrode 212 corresponds to the drain of the first semiconductor element 21.

As shown in FIG. 10, the first gate electrode 213 is positioned on the same side as the first electrode 211 in the first direction z. The first gate electrode 213 receives a gate voltage for driving the first semiconductor element 21. As shown in FIG. 3, the first gate electrode 213 has a smaller area than the first electrode 211 as viewed in the first direction z.

As shown in FIGS. 7-9, the second semiconductor elements 22 are positioned opposite the first terminal 11 with respect to the second terminal 12 in the first direction z. Thus, the second semiconductor elements 22 are positioned opposite the second heat dissipating portions 123 with respect to the second obverse surface 121A of the second terminal 12. In addition, the second semiconductor elements 22 are positioned between the second base 121 of the second terminal 12 and the second connecting portions 145 of the fourth terminal 14 in the first direction z. The second semiconductor elements 22 are accommodated in the cavity 54 of the housing 50. As viewed in the first direction z, the second semiconductor elements 22 overlap with the respective first semiconductor elements 21. The second semiconductor elements 22 are identical to the first semiconductor elements 21. Thus, the second semiconductor elements 22 are n-channel, vertical MOSFETs. The second semiconductor elements 22 are aligned along the second direction x.

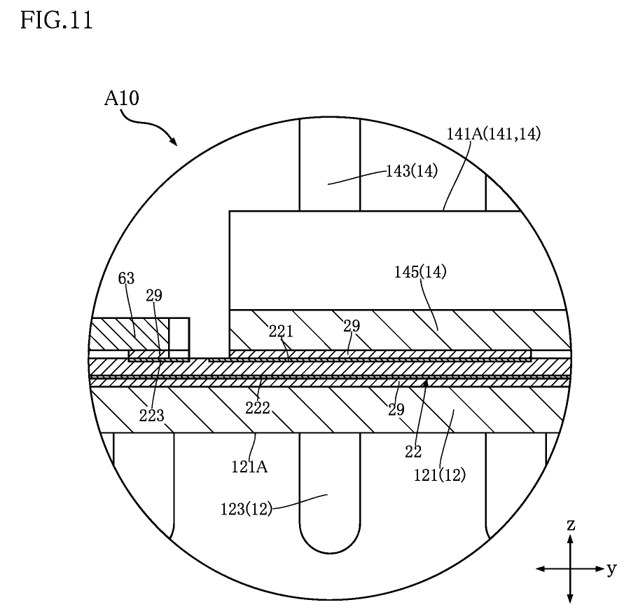

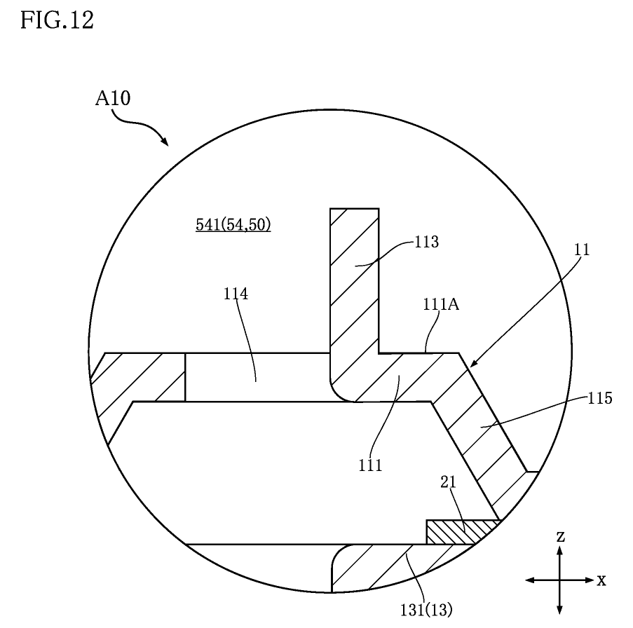

As shown in FIG. 11, each of the second semiconductor elements 22 has a third electrode 221, a fourth electrode 222, and a second gate electrode 223.

As shown in FIG. 11, the third electrode 221 is positioned opposite the side that faces the second base 121 of the second terminal 12 in the first direction z. The third electrode 221 of each second semiconductor element 22 is electrically bonded to one of the second connecting portions 145 of the fourth terminal 14 via a bonding layer 29. As a result, the third electrode 221 is electrically connected to the fourth terminal 14. The third electrode 221 carries the current corresponding to the power after conversion by the second semiconductor element 22. In other words, the third electrode 221 corresponds to the source of the second semiconductor element 22.

As shown in FIG. 11, the fourth electrode 222 faces the second base 121 of the second terminal 12. The fourth electrode 222 is electrically bonded to the second base 121 via the bonding layer 29. The fourth electrode 222 carries the current corresponding to the power before conversion by the second semiconductor element 22. In other words, the fourth electrode 222 corresponds to the drain of the second semiconductor element 22.

As shown in FIG. 11, the second gate electrode 223 is positioned on the same side as the third electrode 221 in the first direction z. The second gate electrode 223 receives a gate voltage for driving the second semiconductor element 22. As viewed in the first direction z, the second gate electrode 223 has a smaller area than the third electrode 221.

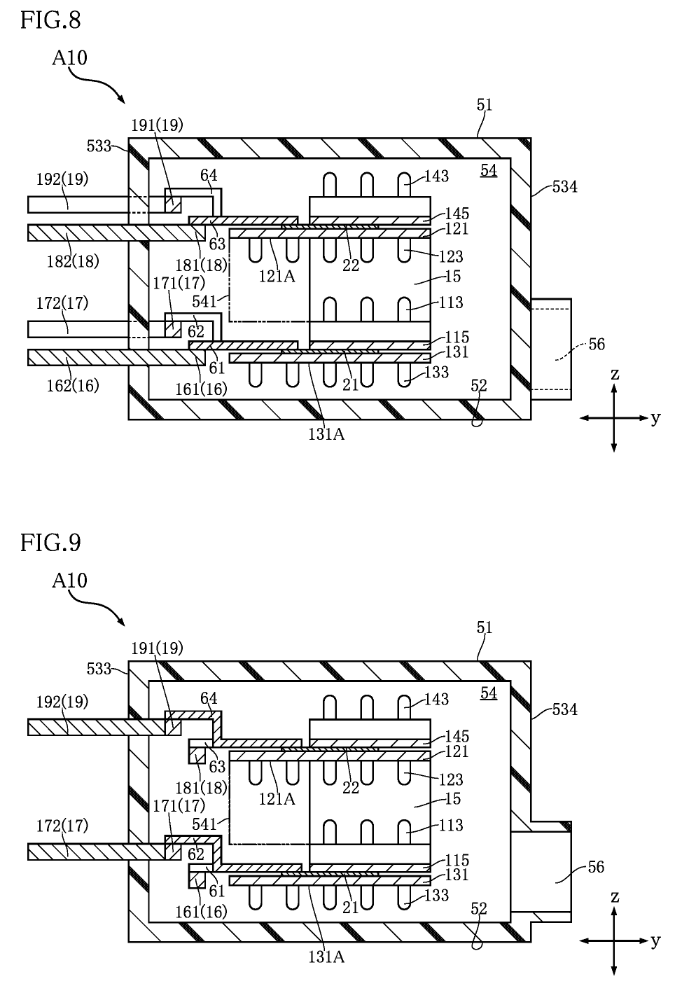

As shown in FIGS. 4 and 5, the first signal terminal 16 is positioned on one side in the third direction y from the first terminal 11 and the third terminal 13. The first signal terminal 16 is supported by the housing 50. The first signal terminal 16 is electrically connected to the first gate electrode 213 of each first semiconductor element 21. The first signal terminal 16 receives a gate voltage for driving the first semiconductor elements 21. The first signal terminal 16 is a metal lead containing copper, for example. The first signal terminal 16 has an inner portion 161 and an outer portion 162. The inner portion 161 is accommodated in the housing 50. The inner portion 161 has a portion accommodated in the cavity 54 of the housing 50. The inner portion 161 has a portion extending in the second direction x. The outer portion 162 is connected to the inner portion 161. As shown in FIG. 8, the outer portion 162 protrudes outward from the third side surface 533 of the housing 50.

Each of the first leads 61 is electrically connected to the first gate electrode 213 of a first semiconductor element 21 and the first signal terminal 16. As shown in FIG. 5, the first leads 61 extend in the third direction y. Each of the first leads 61 is a metal lead containing copper, for example. One end of each first lead 61 in the third direction y is electrically bonded to the first gate electrode 213 of a first semiconductor element 21 via a bonding layer 29. The other end of each first lead 61 in the third direction y is electrically bonded to the inner portion 161 of the first signal terminal 16.

As shown in FIGS. 4 and 5, the second signal terminal 17 is positioned on the same side as the first signal terminal 16 with respect to the first terminal 11 and the third terminal 13 in the third direction y. The second signal terminal 17 is supported by the housing 50. The second signal terminal 17 is electrically connected to the first electrode 211 of each first semiconductor element 21. The second signal terminal 17 receives a voltage that is equal to the voltage applied to the first electrode 211 of each first semiconductor element 21. The second signal terminal 17 is a metal lead containing copper, for example. The second signal terminal 17 has an inner portion 171 and an outer portion 172. The inner portion 171 is accommodated in the housing 50. The inner portion 171 has a portion accommodated in the cavity 54 of the housing 50. The inner portion 171 has a portion extending in the second direction x. As shown in FIGS. 8 and 9, the inner portion 171 is positioned closer to the top surface 51 of the housing 50 than is the inner portion 161 of the first signal terminal 16. The outer portion 172 is connected to the inner portion 171. As shown in FIG. 9, the outer portion 172 protrudes outward from the third side surface 533 of the housing 50.

Each of the second leads 62 is electrically connected to the first electrode 211 of a first semiconductor element 21 and the second signal terminal 17. As shown in FIG. 5, the second leads 62 extend in the third direction y as viewed in the first direction z. As shown in FIG. 9, the second leads 62 extend across the inner portion 161 of the first signal terminal 16. Each of the second leads 62 is a metal lead containing copper, for example. One end of each second lead 62 in the third direction y is electrically bonded to the first electrode 211 of a first semiconductor element 21. The other end of each second lead 62 in the third direction y is electrically bonded to the inner portion 171 of the second signal terminal 17.

As shown in FIGS. 2 and 3, the third signal terminal 18 is positioned on one side in the third direction y from the second terminal 12 and the fourth terminal 14. As viewed in the first direction z, the third signal terminal 18 overlaps with the first signal terminal 16. The third signal terminal 18 is supported by the housing 50. The third signal terminal 18 is electrically connected to the second gate electrode 223 of each second semiconductor element 22. The third signal terminal 18 receives a gate voltage for driving the second semiconductor elements 22. The third signal terminal 18 is a metal lead containing copper, for example. The third signal terminal 18 has an inner portion 181 and an outer portion 182. The inner portion 181 is accommodated in the housing 50. The inner portion 181 has a portion accommodated in the cavity 54 of the housing 50. The inner portion 181 has a portion extending in the second direction x. The outer portion 182 is connected to the inner portion 181. As shown in FIG. 8, the outer portion 182 protrudes outward from the third side surface 533 of the housing 50.

Each of the third leads 63 is electrically connected to the second gate electrode 223 of a second semiconductor element 22 and the third signal terminal 18. As shown in FIG. 3, the third leads 63 extend in the third direction y. Each of the third leads 63 is a metal lead containing copper, for example. One end of each third lead 63 in the third direction y is electrically bonded to the second gate electrode 223 of a second semiconductor element 22 via a bonding layer 29. The other end of each third lead 63 in the third direction y is electrically bonded to the inner portion 181 of the third signal terminal 18.

As shown in FIGS. 2 and 3, the fourth signal terminal 19 is positioned on the same side as the third signal terminal 18 with respect to the second terminal 12 and the fourth terminal 14 in the third direction y. As viewed in the first direction z, the fourth signal terminal 19 overlaps with the second signal terminal 17. The fourth signal terminal 19 is supported by the housing 50. The fourth signal terminal 19 is electrically connected to the third electrode 221 of each second semiconductor element 22. The fourth signal terminal 19 receives a voltage that is equal to the voltage applied to the third electrode 221 of each second semiconductor element 22. The fourth signal terminal 19 is a metal lead containing copper, for example. The fourth signal terminal 19 has an inner portion 191 and an outer portion 192. The inner portion 191 is accommodated in the housing 50. The inner portion 191 has a portion accommodated in the cavity 54 of the housing 50. The inner portion 191 has a portion extending in the second direction x. As shown in FIGS. 8 and 9, the inner portion 191 is positioned closer to the top surface 51 of the housing 50 than is the inner portion 181 of the third signal terminal 18. The outer portion 192 is connected to the inner portion 191. As shown in FIG. 9, the outer portion 192 protrudes outward from the third side surface 533 of the housing 50.

Each of the fourth leads 64 is electrically connected to the third electrode 221 of a second semiconductor element 22 and the fourth signal terminal 19. As shown in FIG. 3, the fourth leads 64 extend in the third direction y as viewed in the first direction z. As shown in FIG. 9, the fourth leads 64 extend across the inner portion 181 of the third signal terminal 18. Each of the fourth leads 64 is a metal lead containing copper, for example. One end of each fourth lead 64 in the third direction y is electrically bonded to the third electrode 221 of a second semiconductor element 22. The other end of each fourth lead 64 in the third direction y is electrically bonded to the inner portion 191 of the fourth signal terminal 19.

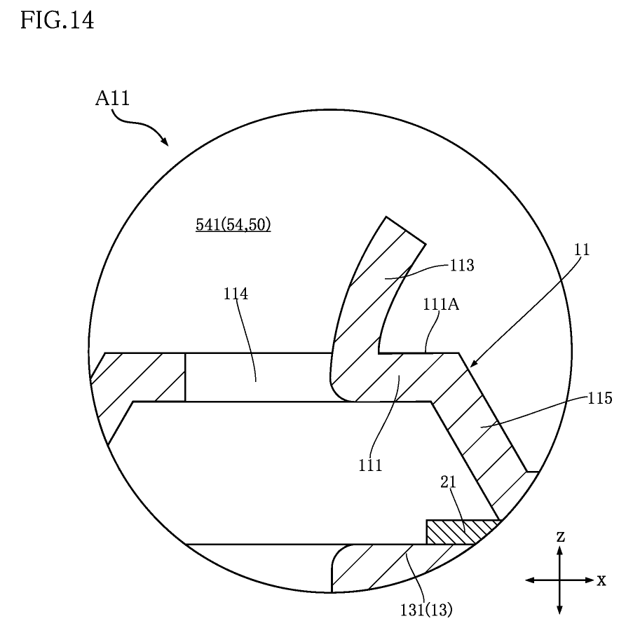

The following describes a semiconductor device A11 according to a first variation of the first embodiment of the present disclosure, with reference to FIG. 14. Note that FIG. 14 corresponds to FIG. 12.

As shown in FIG. 14, the semiconductor device A11 is different from the semiconductor device A10 in the configuration of the first terminal 11. The first heat dissipating portions 113 of the first terminal 11 are curved in the second direction x.

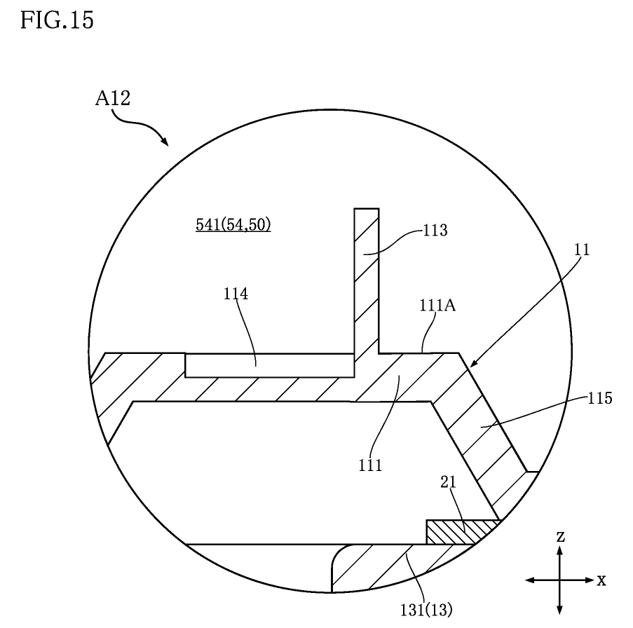

The following describes a semiconductor device A12 according to a second variation of the first embodiment of the present disclosure, with reference to FIG. 15. Note that FIG. 15 corresponds to FIG. 12.

As shown in FIG. 15, the semiconductor device A12 is different from the semiconductor device A10 in the configuration of the first terminal 11. The first openings 114 of the first terminal 11 are recessed from the first obverse surface 111A of the first base 111. The volume of each first heat dissipating portion 113 of the first terminal 11 is smaller than the volume of each first heat dissipating portion 113 of the first terminal 11 in the semiconductor device A10.

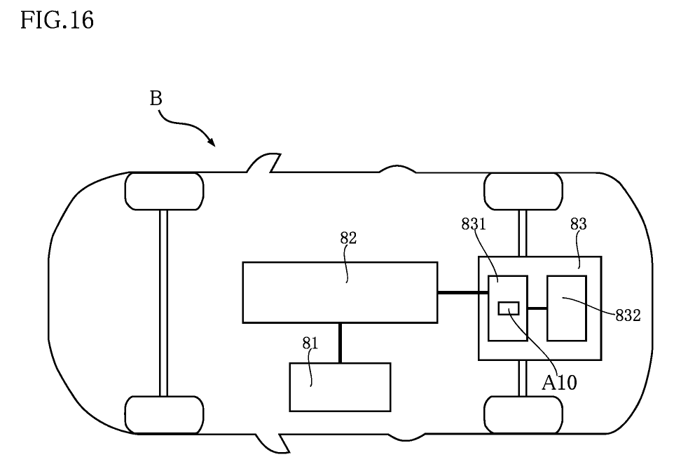

Next, a vehicle B equipped with the semiconductor device A10 will be described with reference to FIG. 16. In one example, the vehicle B is an electric vehicle (EV).

As shown in FIG. 16, the vehicle B includes an on-board charger 81, a storage battery 82, and a drive system 83. The on-board charger 81 wirelessly receives power from an outdoor power supply facility (not shown). Alternatively, the on-board charger 81 may receive power from the power supply facility via a wired connection. The on-board charger 81 includes a step-up DC-DC converter. The converter increases the voltage of the power supplied to the on-board charger 81, and supplies the resulting power to the storage battery 82. The voltage is increased to 600 V, for example.

The drive system 83 drives the vehicle B. The drive system 83 has an inverter 831 and a drive source 832. A semiconductor device A10 forms a part of the inverter 831. The power stored on the storage battery 82 is supplied to the inverter 831. The storage battery 82 supplies DC power to the inverter 831. Unlike the power system shown in FIG. 16, an additional step-up DC-DC converter may be provided between the storage battery 82 and the inverter 831. The inverter 831 converts the DC power to AC power. The inverter 831, including the semiconductor device A10, is electrically connected to the drive source 832. The drive source 832 includes an AC motor and a transmission. When the AC power from the inverter 831 is supplied to the drive source 832, the AC motor rotates and transmits its rotation to the transmission. The transmission reduces the rotational speed transmitted from the AC motor as needed, and rotates the axle of the vehicle B. This causes the vehicle B to drive. While the vehicle B is being driven, the rotational speed of the AC motor needs to be adjusted based on relevant information, such as the position of the accelerator pedal. The semiconductor device A10 in the inverter 831 is used to output the AC power at a frequency appropriately adjusted to correspond to the required rotational speed of the AC motor.

The following describes advantages of the semiconductor device A10.

The semiconductor device A10 includes the first terminal 11 and the first semiconductor elements 21. The first semiconductor elements 21 are electrically bonded to the first terminal 11. The first terminal 11 has the first obverse surface 111A facing one side in the first direction z. The first terminal 11 is provided with the first heat dissipating portions 113 that protrude from the first obverse surface 111A. With this configuration, as shown in FIG. 13, when the coolant 70 flows into the cavity 54 of the housing 50, the coolant 70 makes direct contact with the first heat dissipating portions 113. This improves the cooling efficiency of the semiconductor device A10 as compared to conventional techniques. Thus, with this configuration, it is possible to further improve the cooling efficiency of the semiconductor device A10.

The first terminal 11 is provided with the first openings 114 formed in the first obverse surface 111A. The first openings 114 are connected to the first heat dissipating portions 113. This configuration allows each of the first heat dissipating portions 113 to be formed by bending a portion of the first base 111 of the first terminal 11.

The first openings 114 pass through the first base 111 of the first terminal 11 in the first direction z. This configuration increases the surface area of the first terminal 11 and allows the coolant 70 to flow downward into the first openings 114. As a result, the cooling efficiency of the semiconductor device A10 improves more effectively.

The semiconductor device A10 further includes the second terminal 12 positioned opposite the first semiconductor elements 21 with respect to the first obverse surface 111A of the first terminal 11. The flow path 541 is provided between the first terminal 11 and the second terminal 12 in the first direction z. The first obverse surface 111A and the second obverse surface 121A of the second terminal 12 are in contact with the flow path 541. With this configuration, the coolant 70 makes direct contact with the first terminal 11 and the second terminal 12, thereby further improving the cooling efficiency of the semiconductor device A10.

The second semiconductor elements 22 are electrically bonded to the second terminal 12. The second terminal 12 is provided with the second heat dissipating portions 123 that protrude from the second obverse surface 121A. The second heat dissipating portions 123 are accommodated in the flow path 541. With this configuration, the coolant 70 makes direct contact with the second heat dissipating portions 123, thereby further improving the cooling efficiency of the semiconductor device A10.

The semiconductor device A10 further includes the housing 50 that supports the first terminal 11 and the second terminal 12. The housing 50 is provided with the inlet 55 and the outlet 56. The inlet 55 and the outlet 56 are positioned opposite each other with respect to the first heat dissipating portions 113 of the first terminal 11 in a direction perpendicular to the first direction z. This configuration allows the coolant 70 to flow downward such that the coolant 70 easily makes direct contact with the first heat dissipating portions 113.

### Second Embodiment

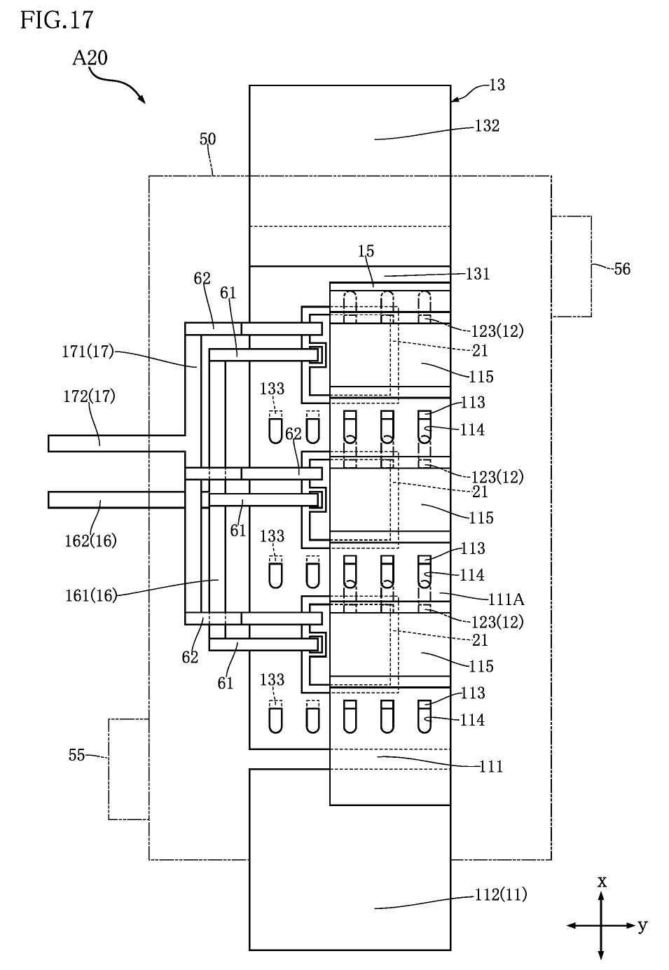

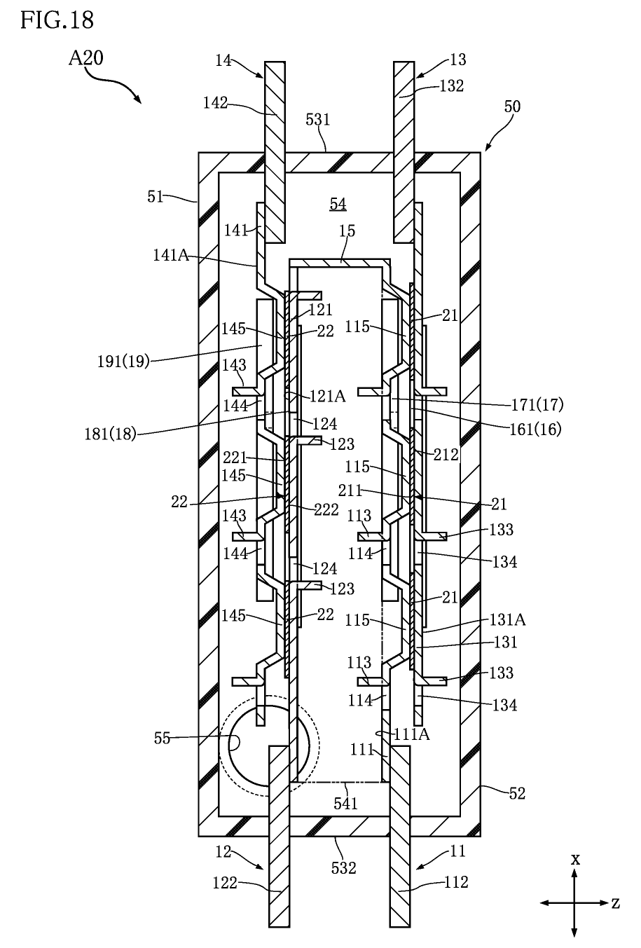

The following describes a semiconductor device A20 according to a second embodiment of the present disclosure, with reference to FIGS. 17 and 18. In these figures, elements that are identical or similar to those of the semiconductor device A10 are indicated by the same reference numerals, and overlapping descriptions are omitted. Note that FIG. 17 corresponds to FIG. 4 that shows the semiconductor device A10. FIG. 18 corresponds to FIG. 7 that shows the semiconductor device A10.

The semiconductor device A20 is different from the semiconductor device A10 in the configuration of the second terminal 12.

As shown in FIGS. 17 and 18, the second heat dissipating portions 123 of the second terminal 12 are spaced apart from the first heat dissipating portions 113 of the first terminal 11, as viewed in the first direction z.

The following describes advantages of the semiconductor device A20.

The semiconductor device A20 includes the first terminal 11 and the first semiconductor elements 21. The first semiconductor elements 21 are electrically bonded to the first terminal 11. The first terminal 11 has the first obverse surface 111A facing one side in the first direction z. The first terminal 11 is provided with the first heat dissipating portions 113 that protrude from the first obverse surface 111A. Thus, with this configuration, it is possible to further improve the cooling efficiency of the semiconductor device A20. Further, the semiconductor device A20 has configurations similar to the semiconductor device A10, thereby achieving the same advantages as the semiconductor device A10.

In the semiconductor device A20, the second heat dissipating portions 123 of the second terminal 12 are spaced apart from the first heat dissipating portions 113 of the first terminal 11, as viewed in the first direction z. This configuration can reduce the concentration of thermal distribution in each of the first terminal 11 and the second terminal 12 caused by heat generated in the first semiconductor elements 21 and the second semiconductor elements 22.

### Third Embodiment

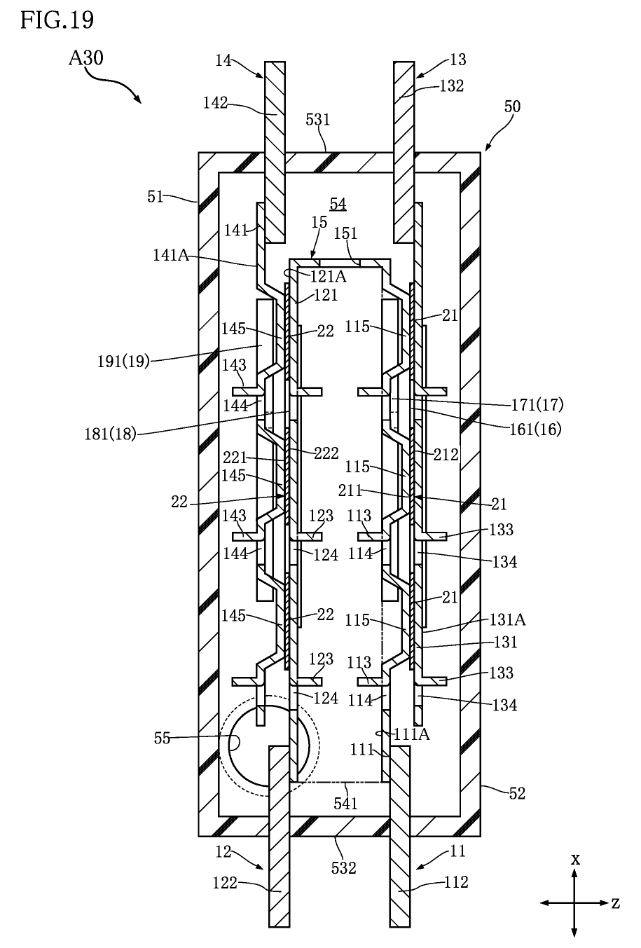

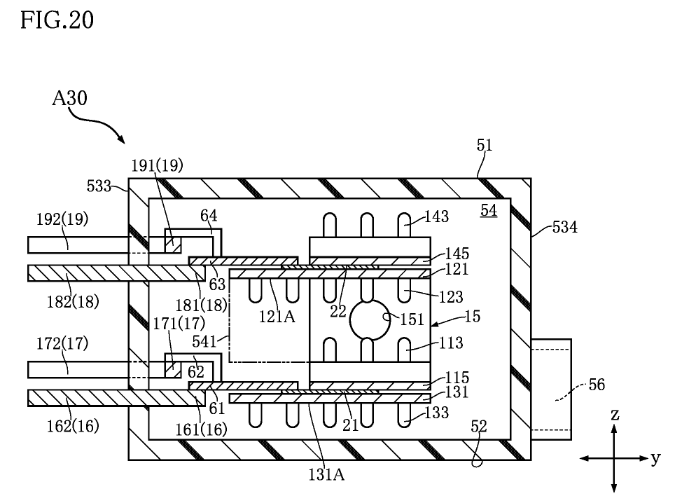

The following describes a semiconductor device A30 according to a third embodiment of the present disclosure, with reference to FIGS. 19 and 20. In these figures, elements that are identical or similar to those of the semiconductor device A10 are indicated by the same reference numerals, and overlapping descriptions are omitted. Note that FIG. 19 corresponds to FIG. 7 that shows the semiconductor device A10. FIG. 20 corresponds to FIG. 8 that shows the semiconductor device A10.

The semiconductor device A30 is different from the semiconductor device A10 in the configuration of the conductive member 15.

As shown in FIGS. 19 and 20, the conductive member 15 is provided with a through portion 151. The through portion 151 passes through the conductive member 15 in the second direction x. The through portion 151 is connected to the flow path 541 of the cavity 54 of the housing 50.

The following describes advantages of the semiconductor device A30.

The semiconductor device A30 includes the first terminal 11 and the first semiconductor elements 21. The first semiconductor elements 21 are electrically bonded to the first terminal 11. The first terminal 11 has the first obverse surface 111A facing one side in the first direction z. The first terminal 11 is provided with the first heat dissipating portions 113 that protrude from the first obverse surface 111A. Thus, with this configuration, it is possible to further improve the cooling efficiency of the semiconductor device A30. Further, the semiconductor device A30 has configurations similar to the semiconductor device A10, thereby achieving the same advantages as the semiconductor device A10.

In the semiconductor device A30, the conductive member 15 is provided with the through portion 151 that extends in a direction perpendicular to the first direction z. The through portion 151 is connected to the flow path 541 of the cavity 54 of the housing 50. This configuration increases the surface area of the conductive member 15 and allows the coolant 70 to flow downward into the through portion 151, thereby improving the cooling efficiency of the semiconductor device A30 more effectively.

### Fourth Embodiment

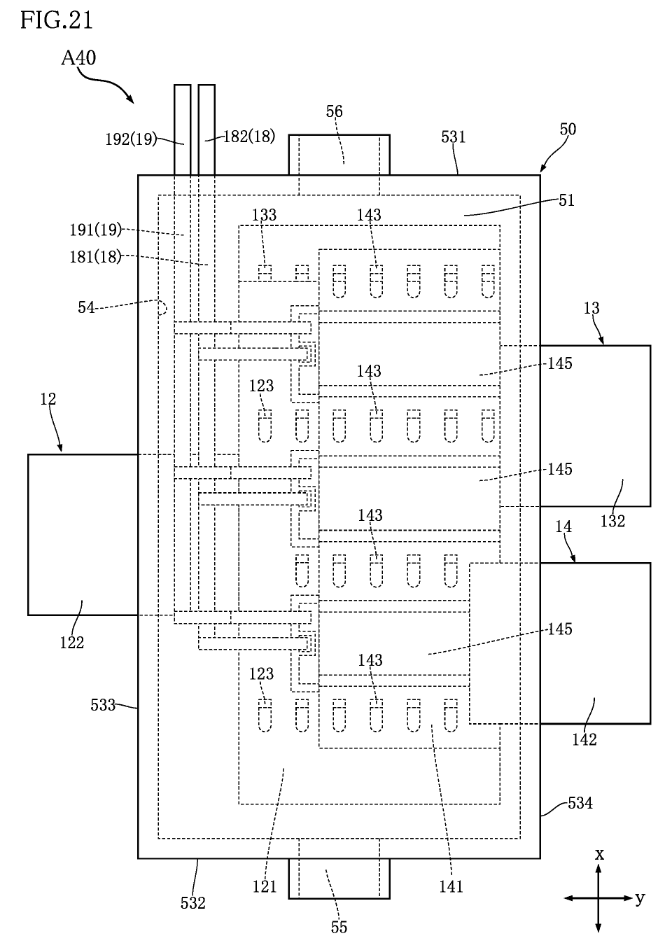

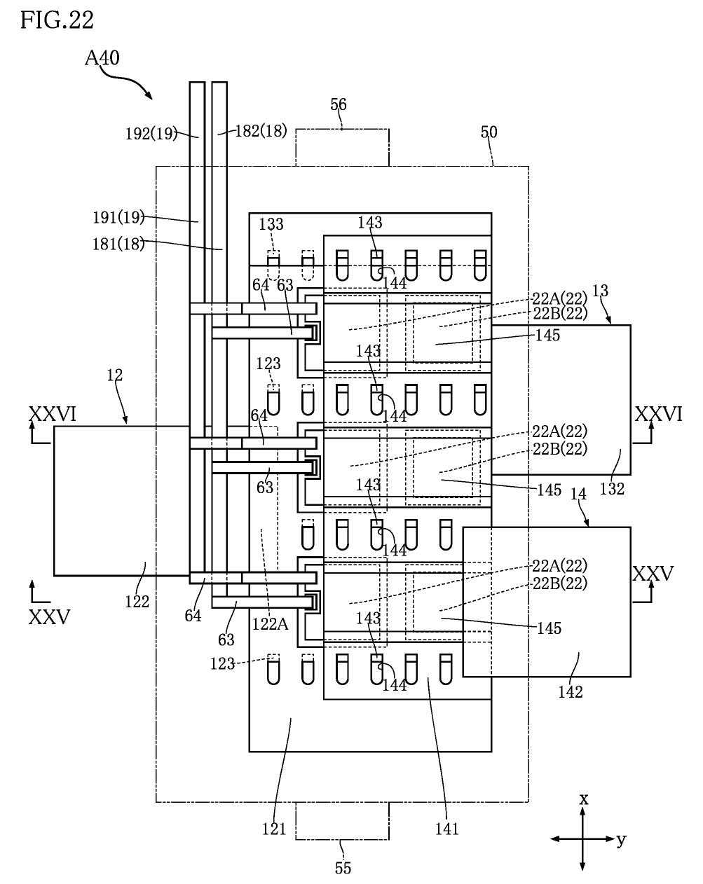

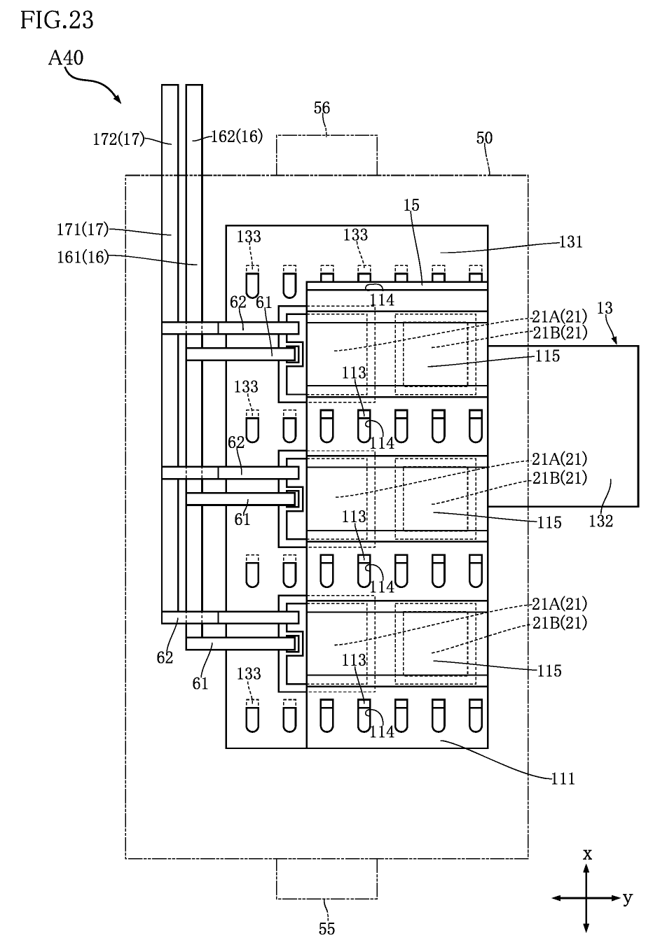

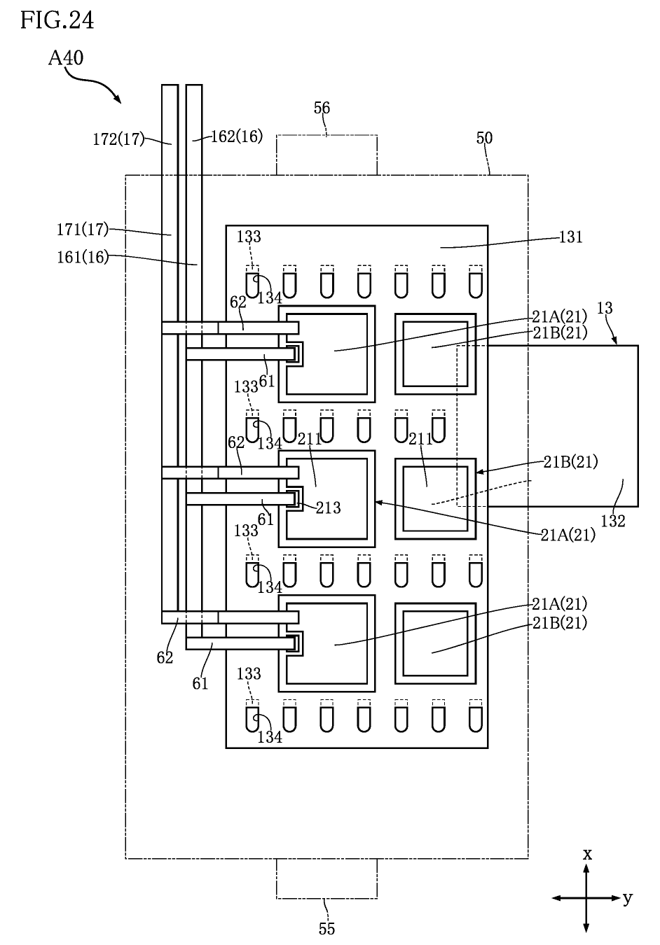

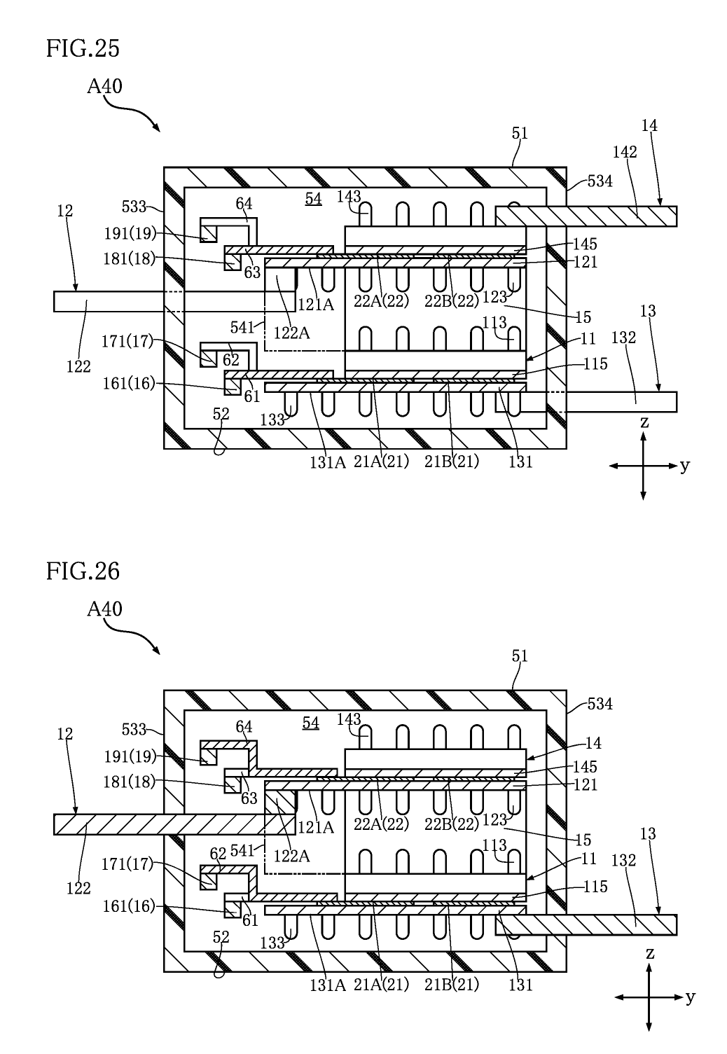

The following describes a semiconductor device A40 according to a fourth embodiment of the present disclosure, with reference to FIGS. 21-26. In these figures, elements that are identical or similar to those of the semiconductor device A10 are indicated by the same reference numerals, and overlapping descriptions are omitted. Note that FIG. 22 corresponds to FIG. 2 that shows the semiconductor device A10. FIG. 23 corresponds to FIG. 4 that shows the semiconductor device A10. FIG. 24 corresponds to FIG. 5 that shows the semiconductor device A10.

The semiconductor device A40 is different from the semiconductor device A10 in the configurations of the first terminal 11, the second terminal 12, the third terminal 13, the fourth terminal 14, the first signal terminal 16, the second signal terminal 17, the third signal terminal 18, the fourth signal terminal 19, the housing 50, the first semiconductor elements 21, and the second semiconductor elements 22.

As shown in FIG. 23, the first terminal 11 does not include the first extension 112. As shown in FIGS. 22 and 26, the second extension 122 of the second terminal 12 is positioned on one side in the third direction y from the second base 121. The second extension 122 is electrically bonded to the second base 121 via a support 122A. As shown in FIGS. 21 and 26, the second extension 122 has a portion protruding outward from the third side surface 533 of the housing 50.

As shown in FIGS. 22, 24, and 25, the third extension 132 of the third terminal 13 and the fourth extension 142 of the fourth terminal 14 are positioned opposite the second extension 122 of the second terminal 12 with respect to the first semiconductor elements 21 and the second semiconductor elements 22 in the third direction y. As shown in FIGS. 21, 25, and 26, each of the third extension 132 and the fourth extension 142 has a portion protruding outward from the fourth side surface 534 of the housing 50. The third extension 132 and the fourth extension 142 are spaced apart from each other in the second direction x.

As shown in FIGS. 21 and 23, the outer portion 162 of the first signal terminal 16 and the outer portion 172 of the second signal terminal 17 protrude outward from the first side surface 531 of the housing 50. As shown in FIGS. 21 and 22, the outer portion 182 of the third signal terminal 18 and the outer portion 192 of the fourth signal terminal 19 protrude outward from the first side surface 531. The outer portion 162, the outer portion 172, the outer portion 182, and the outer portion 192 extend in the second direction x.

As shown in FIG. 21, the inlet 55 of the housing 50 is provided in the second side surface 532 of the housing 50. The outlet 56 of the housing 50 is provided in the first side surface 531.

As shown in FIGS. 23-26, the first semiconductor elements 21 include a plurality of first switching elements 21A and a plurality of first diodes 21B. The first diodes 21B are connected in parallel to the respective first switching elements 21A. Each of the first switching elements 21A has a first electrode 211, a second electrode 212, and a first gate electrode 213. The first switching elements 21A are transistors, such as MOSFETs or IGBTs. In the semiconductor device A40, the first switching elements 21A are MOSFETs, for example. Each of the first diodes 21B includes a first electrode 211 which is an anode, and a second electrode 212 which is a cathode. In the semiconductor device A40, the first diodes 21B function as freewheeling diodes for the first switching elements 21A. In the semiconductor device A40, the first diodes 21B are Schottky barrier diodes, for example.

As shown in FIGS. 22, 25, and 26, the second semiconductor elements 22 include a plurality of second switching elements 22A and a plurality of second diodes 22B. The second diodes 22B are connected in parallel to the respective second switching elements 22A. Each of the second switching elements 22A has a third electrode 221, a fourth electrode 222, and a second gate electrode 223. The second switching elements 22A are identical to the first switching elements 21A. Each of the second diodes 22B has a third electrode 221 which is an anode, and a fourth electrode 222 which is a cathode. In the semiconductor device A40, the second diodes 22B function as freewheeling diodes for the second switching elements 22A. The second diodes 22B are identical to the first diodes 21B.

Thus, as in the semiconductor device A40, the first semiconductor elements 21 may not be all identical, but may include different types of elements. Similarly, the second semiconductor elements 22 may not be all identical, but may include different types of elements.

The following describes advantages of the semiconductor device A40.

The semiconductor device A40 includes the first terminal 11 and the first semiconductor elements 21. The first semiconductor elements 21 are electrically bonded to the first terminal 11. The first terminal 11 has the first obverse surface 111A facing one side in the first direction z. The first terminal 11 is provided with the first heat dissipating portions 113 that protrude from the first obverse surface 111A. Thus, with this configuration, it is possible to further improve the cooling efficiency of the semiconductor device A40. Further, the semiconductor device A40 has configurations similar to the semiconductor device A10, thereby achieving the same advantages as the semiconductor device A10.

The present disclosure is not limited to the above embodiments. Various design changes can be made to the specific configurations of the elements in the present disclosure.

The present disclosure includes the embodiments described in the following clauses.

### Clause 1

A semiconductor device comprising:
a first terminal; and
a first semiconductor element electrically bonded to the first terminal,
wherein the first terminal includes a first obverse surface facing one side in a first direction, and
the first terminal is provided with a first heat dissipating portion that protrudes from the first obverse surface.

### Clause 2

The semiconductor device according to clause 1, wherein the first terminal is provided with a first opening formed in the first obverse surface, and
the first opening is connected to the first heat dissipating portion.

### Clause 3

The semiconductor device according to clause 2, wherein the first semiconductor element is positioned opposite the first heat dissipating portion with respect to the first obverse surface.

### Clause 4

The semiconductor device according to clause 3, wherein the first terminal includes a first base including the first obverse surface, and a first connecting portion connected to the first base,
the first connecting portion protrudes from the first base toward the first semiconductor element in the first direction, and
the first semiconductor element is electrically bonded to the first connecting portion.

### Clause 5

The semiconductor device according to clause 4, wherein the first heat dissipating portion is spaced apart from the first connecting portion.

### Clause 6

The semiconductor device according to clause 5, wherein the first opening passes through the first base in the first direction.

### Clause 7

The semiconductor device according to clause 6, wherein a volume of the first heat dissipating portion is equal to a volume of the first opening.

### Clause 8

The semiconductor device according to clause 6, wherein the first heat dissipating portion extends in the first direction.

### Clause 9

The semiconductor device according to clause 6, wherein the first heat dissipating portion is curved in a direction perpendicular to the first direction.

### Clause 10

The semiconductor device according to any one of clauses 4 to 9, further comprising a second terminal positioned opposite the first semiconductor element with respect to the first obverse surface,
a flow path is provided between the first terminal and the second terminal in the first direction, and
the first heat dissipating portion is accommodated in the flow path.

### Clause 11

The semiconductor device according to clause 10, wherein the second terminal includes a second obverse surface facing the first obverse surface,
the second terminal is provided with a second heat dissipating portion protruding from the second obverse surface, and a second opening formed in the second obverse surface,
the second heat dissipating portion is accommodated in the flow path, and
the second opening is connected to the second heat dissipating portion.

### Clause 12

The semiconductor device according to clause 11, wherein the first obverse surface and the second obverse surface are in contact with the flow path.

### Clause 13

The semiconductor device according to clause 12, wherein the first heat dissipating portion is spaced apart from the second terminal, and
the second heat dissipating portion is spaced apart from the first terminal.

### Clause 14

The semiconductor device according to clause 13, wherein as viewed in the first direction, the second heat dissipating portion overlaps with the first connecting portion.

### Clause 15

The semiconductor device according to clause 14, wherein as viewed in the first direction, the second heat dissipating portion is spaced apart from the first heat dissipating portion.

### Clause 16

The semiconductor device according to clause 13, further comprising a third terminal positioned opposite the first terminal with respect to the first semiconductor element,
wherein the first semiconductor element is electrically bonded to the third terminal.

### Clause 17

The semiconductor device according to clause 16, further comprising a housing,
wherein the first terminal, the second terminal, and the third terminal are supported by the housing, and
the housing is provided with a cavity including the flow path.

### Clause 18

The semiconductor device according to clause 17, wherein the third terminal includes a third obverse surface facing away from a side that faces the first semiconductor element in the first direction,
the third terminal is provided with a third heat dissipating portion protruding from the third obverse surface, and a third opening formed in the third obverse surface,
the third heat dissipating portion is accommodated in the cavity, and
the third opening is connected to the third heat dissipating portion.

### Clause 19

The semiconductor device according to clause 17, further comprising a conductive member that connects the first terminal and the second terminal,
wherein the conductive member is accommodated in the cavity.

### Clause 20

A vehicle comprising:
a drive source; and
the semiconductor device according to clause 10,
wherein the semiconductor device is electrically connected to the drive source.

### Clause 21

The semiconductor device according to clause 3, wherein a thickness of the first heat dissipating portion is no greater than a dimension of the first base in the first direction.

### Clause 22

The semiconductor device according to clause 16, further comprising a second semiconductor element positioned opposite the first terminal with respect to the second terminal,
wherein the second terminal is electrically connected to the first terminal, and
the second semiconductor element is electrically bonded to the second terminal.

### Clause 23

The semiconductor device according to clause 22, wherein as viewed in the first direction, the second semiconductor element overlaps with the first semiconductor element.

### Clause 24

The semiconductor device according to clause 22, further comprising a fourth terminal positioned opposite the second terminal with respect to the second semiconductor element,
wherein the second semiconductor element is electrically bonded to the fourth terminal.

### Clause 25

The semiconductor device according to clause 24, wherein the fourth terminal includes a second base and a second connecting portion connected to the second base,
the second connecting portion protrudes from the second base toward the second semiconductor element in the first direction, and
the second semiconductor element is electrically bonded to the second connecting portion.

### Clause 26

The semiconductor device according to clause 16, further comprising a first signal terminal,
the first semiconductor element includes a first electrode and a second electrode that are positioned opposite each other in the first direction, and a first gate electrode positioned on a same side as the first electrode in the first direction,
the first electrode is electrically bonded to the first connecting portion,
the second electrode is electrically bonded to the third terminal, and
the first gate electrode is electrically connected to the first signal terminal.

### Clause 27

The semiconductor device according to clause 17, wherein the housing includes an inlet and an outlet that are in communication with the cavity, and
the inlet and the outlet are positioned opposite each other with respect to the first heat dissipating portion in a direction perpendicular to the first direction.

### Clause 28

The semiconductor device according to clause 19, wherein the first terminal, the second terminal, and the conductive member are formed from a single member.

### REFERENCE NUMERALS

A10 to A40: Semiconductor device
B: Vehicle
11: First terminal
111: First base
111A: First obverse surface
112: First extension
113: First heat dissipating portion
114: First opening
115: First connecting portion
12: Second terminal
121: Second base
121A: Second obverse surface
122: Second extension
122A: Support
123: Second heat dissipating portion
124: Second opening
13: Third terminal
131: Third base
131A: Third obverse surface
132: Third extension
133: Third heat dissipating portion
134: Third opening
14: Fourth terminal
141: Fourth base
141A: Fourth obverse surface
142: Fourth extension
143: Fourth heat dissipating portion
144: Fourth opening
15: Conductive member
151: Through portion
16: First signal terminal
161: Inner portion
162: Outer portion
17: Second signal terminal
171: Inner portion
172: Outer portion
18: Third signal terminal
181: Inner portion
182: Outer portion
19: Fourth signal terminal
191: Inner portion
192: Outer portion
21: First semiconductor element
21A: First switching element
21B: First diode
211: First electrode
212: Second electrode
213: First gate electrode
22: Second semiconductor element
22A: Second switching element
22B: Second diode
221: Third electrode
222: Fourth electrode
223: Second gate electrode
29: Bonding layer
50: Housing
51: Top surface
52: Bottom surface
531 to 534: First to fourth side surfaces
54: Cavity
541: Flow path
55: Inlet
56: Outlet
61 to
64: First to fourth leads
70: Coolant
81: On-board charger
82: Storage battery
83: Drive system
831: Inverter
832: Drive source
z: First direction
x: Second direction
y: Third direction

1. A semiconductor device comprising:
a first terminal; and
a first semiconductor element electrically bonded to the first terminal,
wherein the first terminal includes a first obverse surface facing one side in a first direction, and
the first terminal is provided with a first heat dissipating portion that protrudes from the first obverse surface.

2. The semiconductor device according to claim 1, wherein the first terminal is provided with a first opening formed in the first obverse surface, and
the first opening is connected to the first heat dissipating portion.

3. The semiconductor device according to claim 2, wherein the first semiconductor element is positioned opposite the first heat dissipating portion with respect to the first obverse surface.

4. The semiconductor device according to claim 3, wherein the first terminal includes a first base including the first obverse surface, and a first connecting portion connected to the first base,
the first connecting portion protrudes from the first base toward the first semiconductor element in the first direction, and
the first semiconductor element is electrically bonded to the first connecting portion.

5. The semiconductor device according to claim 4, wherein the first heat dissipating portion is spaced apart from the first connecting portion.

6. The semiconductor device according to claim 5, wherein the first opening passes through the first base in the first direction.

7. The semiconductor device according to claim 6, wherein a volume of the first heat dissipating portion is equal to a volume of the first opening.

8. The semiconductor device according to claim 6, wherein the first heat dissipating portion extends in the first direction.

9. The semiconductor device according to claim 6, wherein the first heat dissipating portion is curved in a direction perpendicular to the first direction.

10. The semiconductor device according to claim 4, further comprising a second terminal positioned opposite the first semiconductor element with respect to the first obverse surface,
a flow path is provided between the first terminal and the second terminal in the first direction, and
the first heat dissipating portion is accommodated in the flow path.

11. The semiconductor device according to claim 10, wherein the second terminal includes a second obverse surface facing the first obverse surface,
the second terminal is provided with a second heat dissipating portion protruding from the second obverse surface, and a second opening formed in the second obverse surface,
the second heat dissipating portion is accommodated in the flow path, and
the second opening is connected to the second heat dissipating portion.

12. The semiconductor device according to claim 11, wherein the first obverse surface and the second obverse surface are in contact with the flow path.

13. The semiconductor device according to claim 12, wherein the first heat dissipating portion is spaced apart from the second terminal, and
the second heat dissipating portion is spaced apart from the first terminal.

14. The semiconductor device according to claim 13, wherein as viewed in the first direction, the second heat dissipating portion overlaps with the first connecting portion.

15. The semiconductor device according to claim 14, wherein as viewed in the first direction, the second heat dissipating portion is spaced apart from the first heat dissipating portion.

16. The semiconductor device according to claim 13, further comprising a third terminal positioned opposite the first terminal with respect to the first semiconductor element,
wherein the first semiconductor element is electrically bonded to the third terminal.

17. The semiconductor device according to claim 16, further comprising a housing,
wherein the first terminal, the second terminal, and the third terminal are supported by the housing, and
the housing is provided with a cavity including the flow path.

18. The semiconductor device according to claim 17, wherein the third terminal includes a third obverse surface facing away from a side that faces the first semiconductor element in the first direction,
the third terminal is provided with a third heat dissipating portion protruding from the third obverse surface, and a third opening formed in the third obverse surface,
the third heat dissipating portion is accommodated in the cavity, and
the third opening is connected to the third heat dissipating portion.

19. The semiconductor device according to claim 17, further comprising a conductive member that connects the first terminal and the second terminal,
wherein the conductive member is accommodated in the cavity.

20. A vehicle comprising:
a drive source; and
the semiconductor device according to claim 10,
wherein the semiconductor device is electrically connected to the drive source.
